(19) United States
(12) Patent Application Publication
(10) Pub. No.: US 2016/0372712 A1
(43) Pub. Date: Dec. 22, 2016

(54) ELECTROLUMINESCENT DEVICE AND DISPLAY APPARATUS

(71) Applicant: BOE Technology Group Co., Ltd., Beijing (CN)

(72) Inventors: Chin-Lung Liao, Beijing (CN); Zhiqiang Jiao, Beijing (CN)

(21) Appl. No.: 15/089,751

(22) Filed: Apr. 4, 2016

(30) Foreign Application Priority Data
Jun. 18, 2015 (CN) 201510341205.0

(51) Int. Cl. H01L 51/52

(52) U.S. Cl. CPC H01L 51/5271; H01L 51/5218; H01L 51/5234; H01L 51/5253; H01L 2251/301; H01L 2251/308; H01L 2251/5315

(57) ABSTRACT

The present disclosure discloses an electroluminescent device and a display apparatus. This electroluminescent device comprises: a transparent anode, an electroluminescent layer, and a transparent cathode, which are sequentially provided on a substrate; and a reflective layer is provided on one of the side of the transparent anode away from the electroluminescent layer or the side of the transparent cathode away from the electroluminescent layer. In the technical solution described above, the functions of an electrode and reflection are achieved by the use of a transparent electrode and a reflective layer respectively, rather than the use of a metal reflective electrode, such that the problems of the plasma effects of metal reflective electrodes have been solved.

### CROSS-REFERENCE TO RELATED APPLICATION

This application claims the benefits of Chinese Patent Application No. 201510341205.0 filed on Jun. 18, 2015 in the State Intellectual Property Office of China, whole disclosures of which is incorporated herein by reference.

### TECHNICAL FIELD

At least one embodiment of the present disclosure relates to an electroluminescent device and a display apparatus.

### BACKGROUND

An electroluminescent device typically comprises an anode, an electroluminescent layer, and a cathode, which are sequentially provided. Herein, the electroluminescent layer may be an inorganic electroluminescent layer or an organic electroluminescent layer. After applying a voltage to the electrodes, luminescent centers in the electroluminescent layer are led to light emission. When used for display function, a luminescent device is typically plate-like, and color changes are observed by using one side of the plate as a light-outgoing side.

### SUMMARY

At least one embodiment of the present disclosure provides an electroluminescent device, wherein said electroluminescent device comprises: a transparent anode, an electroluminescent layer, and a transparent cathode, which are sequentially provided on a substrate; and a reflective layer is provided on one of the side of said transparent anode away from said electroluminescent layer or the side of said transparent cathode away from said electroluminescent layer.

In the technical solution described above, by providing a reflective layer on the outer side of a transparent electrode, rather than using an electrode itself as a reflective layer, the general problem of plasma effect, which is generated due to that the metal reflective electrode is too close to the light-emitting layer, is eliminated.

In some embodiments, an encapsulating layer, a reflective layer, and an encapsulating cover plate are sequentially provided on the side of the transparent cathode away from said electroluminescent layer. This structure is advantageous to the production and assembly of electroluminescent devices.

In some embodiments, when said reflective layer is provided on the side of said transparent anode away from said electroluminescent layer, said reflective layer is provided on said substrate.

In some embodiments, said electroluminescent layer is an organic electroluminescent layer, said reflective layer is a metal reflective layer or an alloy reflective layer. In the device of the present disclosure, even if a metal or alloy reflective layer is still used as a reflective layer, the distance between the metal or alloy reflective layer and the light-emitting layer is increased, and the plasma effect on the surface of the metal reflective layer is weakened, such that the consumption of optical energy by the metal reflective layer is effectively reduced and the light-emission efficiency of the device is improved.

Optionally, said metal reflective layer is an aluminum layer, a magnesium layer, or a silver layer. The metal reflective layer is produced by using various materials. Optionally, the alloy reflective layer is formed by two or more metals selected from magnesium, silver, niobium, and aluminum, preferably a niobium-aluminum alloy layer.

Optionally, said transparent cathode is a cathode produced from a transparent metal oxide. It has good conductivity.

Optionally, said transparent cathode is a cathode produced from an indium zinc oxide material. It has good conductivity.

Optionally, said encapsulating layer is an encapsulating adhesive layer, and said encapsulating adhesive layer has a refractive index between 1.5 and 2.0. It has good light transmittance.

Optionally, said encapsulating adhesive layer has a refractive index of 1.9. It has good light transmittance.

Optionally, said anode on the substrate is an indium tin oxide electrode, and said indium tin oxide electrode has a surface resistance less than 30Ω/mm².

At least one embodiment of the present disclosure provides a display apparatus comprising said electroluminescent device described above.

### BRIEF DESCRIPTION OF THE DRAWINGS

FIG. 1 is a structural schematic diagram of a bottom emission type organic electroluminescent device in related art;

FIG. 2 is a structural schematic diagram of an electroluminescent device provided in at least one embodiment of the present disclosure;

FIG. 3 is a structural schematic diagram of an electroluminescent device provided in at least one embodiment of the present disclosure;

FIG. 4 is a schematic diagram of current density-voltage curve variations of an electroluminescent device in the related art and an electroluminescent device provided in some embodiments of the present disclosure;

FIG. 5 is a diagram of current density-luminance curve variations of an organic electroluminescent device in the related art and an organic electroluminescent device provided in some embodiments of the present disclosure; and

FIG. 6 is a current density-current efficiency curve of an organic electroluminescent device in the related art and an organic electroluminescent device provided in some embodiments of the present disclosure.

### DETAILED DESCRIPTION

In order to solve the problem of the plasma effect generated by the metal reflective electrode, some embodiments of the present disclosure provides an electroluminescent device. In the technical solution of some embodiments of the present disclosure, a reflective layer is provided on the side of a transparent anode or a transparent cathode away from a light-emitting layer. The configuration of the present disclosure has the advantage that the functions of an electrode and reflection are achieved by the use of two layers respectively. The reflective layer may be a metal reflective layer or a non-metal reflective layer. When the reflective layer is a non-metal layer, the plasma effect does not exist. Even if common metal reflective layers are used for reasons of cost, etc., since the distance between the metal reflective layer and the light-emitting layer is relatively large, the plasma effect on the surface thereof is greatly weakened, and the consumption of optical energy by the cathode is effectively reduced, such that the light-emission efficiency of the device is improved. For the convenience of understanding the technical solution of the present disclosure, detailed descriptions are made to the technical solution of the present disclosure in conjunction with figures and specific Examples.

Organic electroluminescent devices are exemplified. As shown in FIG. 1, FIG. 1 shows a structural schematic diagram of a bottom emission type organic electroluminescent device in the related art, which comprises a substrate 6 and an encapsulating cover plate 1 which are cell-assembled, and a transparent anode 5, an organic functional layer 4, a metal reflective cathode 3, and an encapsulating layer 2, which are sequentially laminated between the substrate 6 and the encapsulating cover plate 1 along the direction from the substrate 6 to the encapsulating cover plate 1. The substrate 6 is the light-outgoing side. In this configuration, in order to achieve non-transparent display and simplify the structure of the device, the cathode is provided as a metal electrode having the function of reflection, simply referred to as a metal reflective cathode. However, the metal reflective cathode is relatively close to the light-emitting layer, and thus rays emitted from the light-emitting layer will generate a plasma effect on the surface of the metal reflective cathode nearby and consumes a certain amount of optical energy, which reduces the light-emission efficiency of the organic electroluminescent device. This is particularly disadvantageous in high-quality display.

As for top emission type organic electroluminescent devices, transparent materials are used as light-emission cathodes, and anodes are typically provided as metal reflective anodes. Again, metal reflective anodes are relatively close to light-emitting layers, and will generate disadvantageous plasma effects on surfaces.

As for electroluminescent devices having inorganic electroluminescent layers, the same problem still exists.

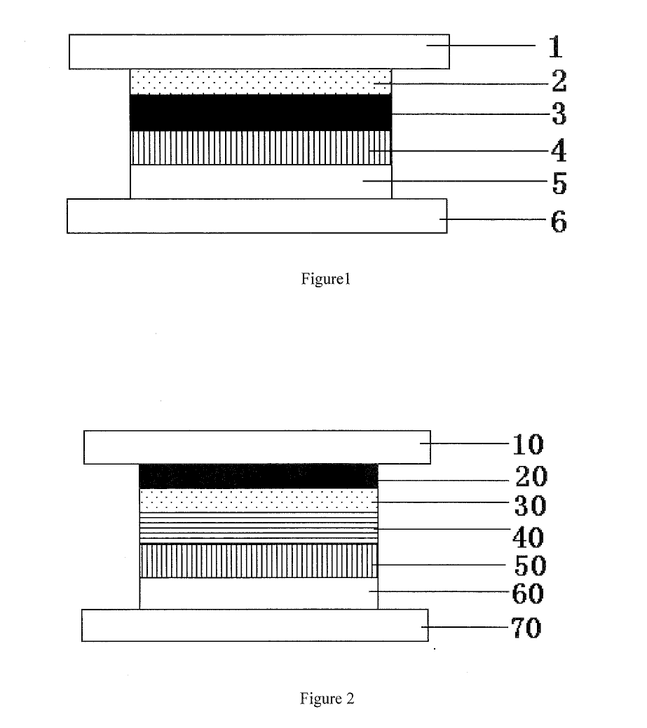

As shown in FIG. 2, FIG. 2 shows a structural schematic diagram of an electroluminescent device provided in at least one embodiment of the present disclosure.

One or more embodiments of the present disclosure provide an electroluminescent device, which comprises: a substrate 70, a transparent anode 60 provided on the substrate 70, an electroluminescent layer 50 provided on the transparent anode 60, and a transparent cathode 40 provided on the electroluminescent layer 50, and further comprises an encapsulating layer 30 provided on the transparent cathode 40 and an encapsulating cover plate 10 provided on the encapsulating layer 30, wherein, a reflective layer 20 is provided on the face of the encapsulating cover plate 10 toward the encapsulating layer 30.

In the technical solution described above, the transparent cathode 40 is used as a cathode, and the reflective layer 20 is provided on the encapsulating cover plate 10 on the outer side of the encapsulating layer 30. When the reflective layer 20 is metal, the distance between the metal reflective layer 20 and the light-emitting layer is increased, and the plasma effect on the surface of the metal reflective layer 20 is weakened, such that the consumption of optical energy by the metal reflective layer 20 is effectively reduced and the light-emission efficiency of the device is improved. When the reflective layer 20 is not a metal reflective layer, the plasma effect does not exist, and the light-emission efficiency of the device is also improved.

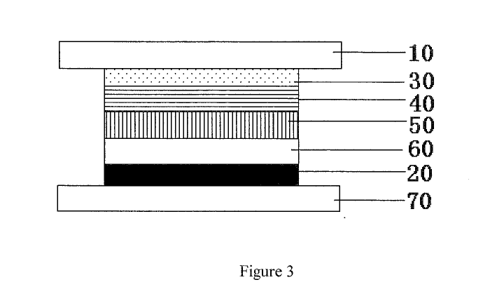

As shown in FIG. 3, FIG. 3 shows a structural schematic diagram of an electroluminescent device provided in another Example of the present disclosure.

The electroluminescent device of this Example comprises: a substrate 70, and a reflective layer 20, a transparent anode 60, an electroluminescent layer 50, a transparent cathode 40, and an encapsulating cover plate 10, which are sequentially provided on the substrate 70. When the reflective layer 20 is metal, the distance between the metal reflective layer 20 and the light-emitting layer is increased, and the plasma effect on the surface of the metal reflective layer 20 is weakened, such that the consumption of optical energy by the metal reflective layer 20 is effectively reduced and the light-emission efficiency of the device is improved. When the reflective layer 20 is not a metal reflective layer, the plasma effect does not exist, and the light-emission efficiency of the device is also improved.

In order to eliminate or weaken the problem of the plasma effect on the surface of the metal reflective electrode close to the electroluminescent layer, the structure of the present disclosure does not use any metal reflective electrode, but provides the reflective layer on the outer side of the electrode. This requires that the electrode on the same side as the reflective layer is substantially transparent. Of course, it is also required that the electrode on the light-outgoing side is substantially transparent. Therefore, the anode and the cathode of the present disclosure are substantially transparent.

An encapsulating layer and an encapsulating cover plate may be provided on the outer side of the cathode. In this case, a reflective layer may be provided between the encapsulating layer and the encapsulating cover plate and is further away from the electroluminescent layer, and the reflective layer is not in contact with the cathode. Preferably, the reflective layer may be previously formed on the encapsulating cover plate, which facilitates production and installation.

When on the anode side, the reflective layer may be directly formed on the substrate, and the anode is subsequently formed on the reflective layer.

The electroluminescent layer in the electroluminescent device of the present disclosure may be an organic electroluminescent layer or an inorganic electroluminescent layer. The organic electroluminescent layer is preferable.

The reflective layer of the present disclosure may be a metal reflective layer or other reflective layers. In view of cost, the metal reflective layer is preferable. A niobium-aluminum alloy layer, an aluminum layer, a magnesium layer, or a silver layer is more preferable.

Preferable transparent anodes comprise indium tin oxide. Preferable transparent cathode materials comprise indium zinc oxide.

For the convenience of more profoundly understanding the structure and the effect of Examples of the present disclosure, detailed descriptions are made to them in conjunction with figures and specific Examples.

In some embodiments, the electroluminescent device of the present disclosure is a bottom emission type organic electroluminescent blue ray device.

With continued reference to FIG. 2, the organic electroluminescent device provided in this Example is a bottom emission organic electroluminescent device. It can be seen from FIG. 2 that the entire organic electroluminescent device comprises a substrate 70 and an encapsulating cover plate 10, and an anode 60, an organic functional layer 50, a transparent cathode 40, an encapsulating layer 30, and a metal reflective layer 20 are sequentially provided between the substrate 70 and the encapsulating cover plate 10.

In a particular provision, the substrate 70 therein is a glass substrate 70. When the transparent anode 60 is adhered to the glass substrate 70, an indium tin oxide (ITO)thin film is first formed on the glass substrate 70, an ITO pattern electrode (i.e., an anode 60) is formed through photolithography thereafter, and then the glass substrate is sequentially washed in deionized water, acetone, and absolute ethanol in an ultrasonic environment. After the washing is completed, the glass substrate is dried with N₂ and is subjected to the treatment of O₂ plasma. In a particular provision of the transparent anode 60, the transparent anode 60 has a thickness of about 150 nm, and the indium tin oxide electrode has a surface resistance less than 30Ω/mm².

A treated substrate is subsequently placed in a vapor deposition chamber, and an organic functional layer 50 is formed on the transparent anode 60 in a manner of vacuum thermal vapor deposition after the degree of vacuum is reduced to less than 5×10⁻⁴ Pa. Herein, the organic functional layer 50 of this Example comprises: a hole injection layer, a hole transport layer, an organic light-emitting layer, an electron transport layer, and an electron injection layer, which are sequentially provided by lamination along the direction from the substrate 70 to the encapsulating cover plate 10. Herein, the organic light-emitting layer is a blue light-emitting layer. In a particular production, a hole injection layer LG101 having a thickness of 5 nm, a hole transport layer, which is N,N′-diphenyl-N,N′-(1-naphthyl)-1,1′-biphenyl-4,4′-diamine (NPB), having a thickness of 40 nm, a blue light-emitting layer MAND:DSA-Ph (3%) having a thickness of 30 nm, an electron transport layer, which is diphenylo-phenanthroline (Bphen) having a thickness of 35 nm, and an electron buffering layer LiF having a thickness of 1 nm are sequentially deposited on the surface of the anode 60; an open mask is used in each layer and the evaporation rate is 0.1 nm/s; and The device has a light-emitting area of 3 mm×3 mm. In a particular production, the host material to be doped in the blue light-emitting layer provided in this Example is MAND (2-methyl-9,10-bis(naphthalen-2-yl)anthracene) and the dopant in the blue light-emitting layer is DSA-Ph (1-4-bis-[4-(N,N-diphenyl)amino]styryl-benzene).

After the organic functional layer 50 is formed, a transparent cathode 40 is provided on the organic functional layer 50. The transparent cathode 40 provided in this Example may be produced by using various materials. Preferably, a cathode produced from transparent metal oxide is used as the transparent cathode 40. As a preferable technical solution, the cathode provided in this Example is a cathode produced from an indium zinc oxide (IZO) material. Indium zinc oxide has good conductive characteristics and light transmittance. Particularly, in production, the device after the organic functional layer 50 is formed is transferred to a magnetron sputtering system for the production of IZO (130 nm). In the process of vapor deposition, a cathode sputtering mask is used, and the evaporation rate is 0.5 nm/s.

Finally, the device is encapsulated in a N₂ glove box, an encapsulating cover plate 10 having a metal reflective layer 20 with an encapsulating adhesive layer attached is laminated with a substrate 70 having a transparent anode 60, an organic functional layer 50, and a transparent cathode 40, followed by ultraviolet radiation, such that the encapsulating layer 30 is cured. Particularly, herein, the encapsulating adhesive layer is used as the encapsulating layer 30, and the encapsulating adhesive layer has a refractive index between 1.5-2.0, for example, any refractive index between 1.5-2.0, such as 1.5, 1.6, 1.7, 1.8, 1.9, 2.0, etc. Preferably, the encapsulating adhesive layer has a refractive index of 1.9. In addition, with respect to the metal reflective layer 20 therein, various metal materials may be used to produce the reflective layer. Particularly, for example, the metal reflective layer 20 is a metal material having good reflective properties, such as an aluminum layer, a magnesium layer, a silver layer, or the like, for reflection. In a particular provision, the metal reflective layer 20 is coated or plated onto the encapsulating cover plate 10. In this Example, an Al layer plated on the encapsulating cover plate is used.

It can be seen from the above description that, by comparing the position where the metal reflective layer 20 is provided to organic electroluminescent devices using metal reflective cathodes provided in the related art, the distance from the luminescent device is increased, and the plasma effect on the surface of the metal reflective layer 20 is weakened, such that the consumption of optical energy by the metal reflective layer 20 is effectively reduced and the light-emission efficiency of the device is improved.

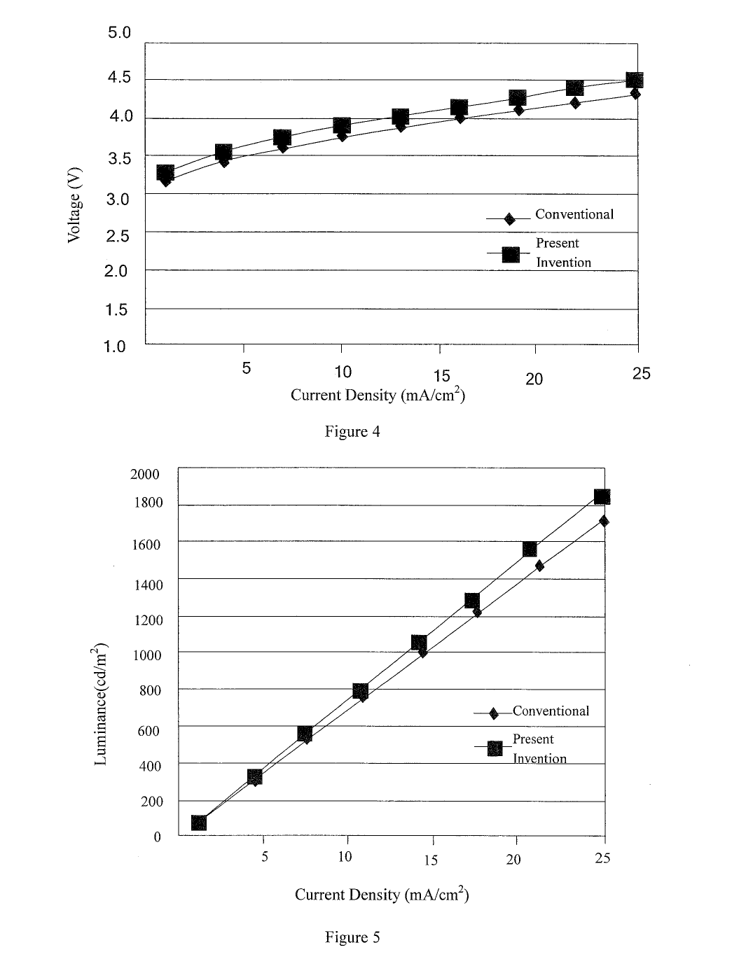

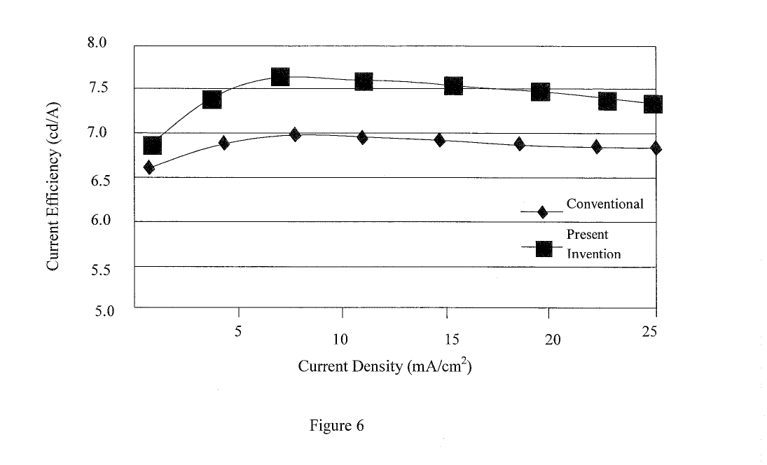

In order to further exhibit the effect of the organic electroluminescent device provided in this Example, the properties of the organic electroluminescent device provided in this Example and those of an organic electroluminescent device in the related art are compared, wherein the organic electroluminescent device as shown in FIG. 1 provided in the background art is used as the structure of the organic electroluminescent device in the related art. FIG. 4, FIG. 5, and FIG. 6 are referred together, wherein FIG. 4 is a schematic diagram of current density-voltage curve variations of an organic electroluminescent device in the related art and an organic electroluminescent device provided in some embodiments of the present disclosure; FIG. 5 is a diagram of current density-luminance curve variations of an organic electroluminescent device in the related art and an organic electroluminescent device provided in some embodiments of the present disclosure; and FIG. 6 is a current density-current efficiency curve of an organic electroluminescent device in the related art and an organic electroluminescent device provided in some embodiments of the present disclosure.

Particularly, FIG. 4 is a diagram of current density-voltage curve variations of the device at different current densities. It can be seen from the figures that, with respect to the organic electroluminescent device in the related art wherein metal Al is used as a metal reflective cathode, the device of this Example, in which a transparent cathode 40 is combined with an encapsulating cover plate 10 having a metal reflective layer 20, has a slightly higher voltage at the same current density. This is because the work function of the transparent cathode 40 formed from IZO is not completely matched to the electron injection layer.

FIG. 5 is a diagram of current density-luminance curve variations of the device at different current densities. At the same current density, the device provided in the Example of the present disclosure has a higher luminance than that of the device having a conventional structure. In addition, it can be seen from FIG. 6 (a diagram of current density-current efficiency curve variations) that the device using the structure provided in the Example of the present disclosure has a higher light-emission efficiency than that of a conventional device structure, and the current efficiency is increased from 6.59 cd/A to 7.59 cd/A, i.e., by an increment of up to 10%.

Therefore, by comparing this Example and the related art, the structure used, wherein a transparent cathode 40 is combined with an encapsulating cover plate 10 having a metal reflective layer 20, may effectively alleviate the surface plasma effect of metal cathodes in the related art, reduce the consumption of optical energy, and improve light output of the device, thereby improving the light-emission efficiency of the device.

In the related art, however, the light emitted from a luminescent center is toward all directions, and thus the electrode on the non-light-outgoing side is typically produced as a reflective one in order to increase the luminance obtained from the light-outgoing side. Metals are typically used as reflective electrodes due to both good conductivities and good light reflectivities.

The present disclosure further provides a display apparatus, comprising the electroluminescent device as described above, such as an organic electroluminescent device. The display apparatus includes any apparatuses for display, such as televisions, computers, cell phones, digital cameras, ATMs, game consoles, electronic advertising boards, smart wearable devices, medical devices, etc.

Understandably, the person skilled in the art may perform various modifications and variations on the present disclosure without deviating from the spirit and the scope of the present disclosure. Thus, if these modifications and variations of the present disclosure are within the scope of the claims of the present disclosure and equivalent techniques thereof, the present disclosure also intends to encompass these modifications and variations.

What is claimed is:

1. An electroluminescent device, comprising: a transparent anode, an electroluminescent layer, and a transparent cathode, which are sequentially provided on a substrate; and
a reflective layer is provided on one of the side of the transparent anode away from the electroluminescent layer or the side of the transparent cathode away from the electroluminescent layer.

2. The electroluminescent device according to claim 1, wherein an encapsulating layer, a reflective layer, and an encapsulating cover plate are sequentially provided on the side of the transparent cathode away from the electroluminescent layer.

3. The electroluminescent device according to claim 1, wherein when the reflective layer is provided on the side of the transparent anode away from the electroluminescent layer, the reflective layer is provided on the substrate.

4. The electroluminescent device according to claim 1, wherein the reflective layer is a metal reflective layer or an alloy reflective layer.

5. The electroluminescent device according to claim 4, wherein the metal reflective layer is an aluminum layer, a magnesium layer, or a silver layer; and
the alloy reflective layer is a niobium-aluminum alloy layer.

6. The electroluminescent device according to claim 1, wherein the transparent cathode is a cathode produced from a transparent metal oxide.

7. The electroluminescent device according to claim 6, wherein the transparent cathode is a cathode produced from an indium zinc oxide material.

8. The electroluminescent device according to claim 1, wherein the encapsulating layer is an encapsulating adhesive layer, the encapsulating adhesive layer has a refractive index in a range of 1.5-2.0.

9. The electroluminescent device according to claim 8, wherein the encapsulating adhesive layer has a refractive index of 1.9.

10. The electroluminescent device according to claim 1, wherein the anode is an indium tin oxide electrode, and the indium tin oxide electrode has a surface resistance less than 30Ω/mm².

11. The electroluminescent device according to claim 1, wherein the electroluminescent layer is an organic electroluminescent layer.

12. A display apparatus, comprising the electroluminescent device according to claim 1.
